(19) United States
(12) Patent Application Publication
(10) Pub. No.: US 2026/0343807 A1
(43) Pub. Date: Oct. 29, 2026

(54) SERVER IMMERSION COOLING SYSTEM WITH REDUCED FLOW RESISTANCE

(71) Applicant: Super Micro Computer, Inc., San Jose, CA (US)

(72) Inventors: Chun An LIANG, New Taipei City (TW); Chih-Yeh LIN, New Taipei City (TW); Cheng Wei LIU, New Taipei City (TW); Chiao Rung HSU, New Taipei City (TW); Tsung-Yen LO, New Taipei City (TW); Wei-Yu CHEN, New Taipei City (TW); Jui-Chi LEE, New Taipei City (TW); Yueh-Ming LIU, New Taipei City (TW); Yi-Hsuan CHEN, New Taipei City (TW)

(21) Appl. No.: 19/190,239

(22) Filed: Apr. 25, 2025

(51) Int. Cl. H05K 7/20

(52) U.S. Cl. CPC H05K 7/20272; H05K 7/20236; H05K 7/20263; H05K 7/20772

(57) ABSTRACT

Disclosed is an immersion cooling system that reduces flow resistance of a dielectric coolant. The immersion cooling system includes an immersion tank that contains the dielectric coolant. Electronic components are submerged in the dielectric coolant in the immersion tank. A fine bubble generator disposed between the immersion tank and a heat exchanger, and receives the dielectric coolant and air from the immersion tank. Fine bubbles are generated by dispersing the air from the immersion tank into the dielectric coolant in the fine bubble generator. The fine bubbles and the dielectric are circulated to the immersion tank.

### TECHNICAL FIELD

The present disclosure is directed to immersion cooling of server computer systems.

### BACKGROUND

Immersion cooling is an established thermal management technique used to dissipate heat from high-performance electronic components. In immersion cooling systems, the electronic components are submerged in a dielectric coolant that directly contacts the surfaces of the components, thereby absorbing and transporting heat away during operation. While immersion cooling systems provide effective thermal transfer, there remains a need to further improve coolant circulation and reduce flow resistance within the cooling loop. High flow resistance can limit the efficiency of coolant movement, increase the load on pumping equipment, and lead to suboptimal heat dissipation performance.

### BRIEF SUMMARY

In one embodiment, an immersion cooling system comprises an immersion tank, a coolant distribution unit (CDU), and a fine bubble generator. The immersion tank contains a single-phase dielectric coolant, wherein electronic modules are submerged in the single-phase dielectric coolant in the immersion tank. The CDU comprises a pump and a heat exchanger, the CDU is coupled to draw the single-phase dielectric coolant from the immersion tank, cool the single-phase dielectric coolant, and discharge the single-phase dielectric coolant to the immersion tank in a first cooling loop. The fine bubble generator is disposed between the CDU and the immersion tank in the first cooling loop. The fine bubble generator receives the single-phase dielectric coolant, generates fine bubbles using air received from the immersion tank, and discharges the single-phase dielectric coolant and the fine bubbles.

In another embodiment, a method of immersion cooling electronic components includes submerging a plurality of electronic components in a dielectric coolant in an immersion tank. The dielectric coolant is received in a fine bubble generator. Air from the immersion tank is received in the fine bubble generator. Fine bubbles are generated by dispersing the air received from the immersion tank into the dielectric coolant in the fine bubble generator. The fine bubbles and the dielectric coolant are circulated to the immersion tank.

In yet another embodiment, an immersion cooling system comprises an immersion tank, a heat exchanger, and a fine bubble generator. The immersion tank contains a dielectric coolant, wherein a plurality of electronic components is submerged in the dielectric coolant. The heat exchanger comprises a first port that is coupled to an outlet of the immersion tank and a second port that is coupled to an inlet of the immersion tank. The fine bubble generator comprises an intake port that receives the dielectric coolant, a gas port that receives air from the immersion tank for generating fine bubbles, and a discharge port that discharges the fine bubbles and the dielectric coolant.

These and other features of the present disclosure will be readily apparent to persons of ordinary skill in the art upon reading the entirety of this disclosure, which includes the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 shows a block diagram of an immersion cooling system, in accordance with an embodiment of the present invention.

FIG. 2 shows a block diagram of an immersion cooling system, in accordance with another embodiment of the present invention.

FIG. 3 shows a flow chart of a method of immersion cooling electronic components, in accordance with an embodiment of the present invention.

### DETAILED DESCRIPTION

In the present disclosure, numerous specific details are provided, such as examples of systems, components, and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

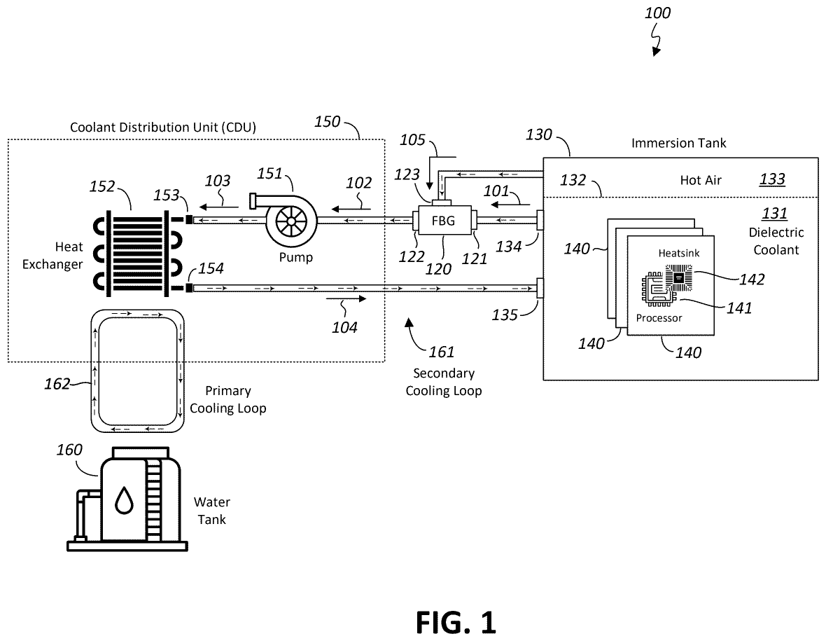

FIG. 1 shows a block diagram of an immersion cooling system 100, in accordance with an embodiment of the present invention. The immersion cooling system 100 includes a coolant distribution unit (CDU) 150, an immersion tank 130, and a fine bubble generator (FBG) 120.

The immersion tank 130 has a dielectric coolant 131, which is a liquid. In one embodiment, the system 100 is a single-phase immersion system in that the dielectric coolant 131 is a single-phase dielectric coolant. A single-phase dielectric coolant remains in the liquid phase throughout the heat absorption and dissipation process, without undergoing a phase change to vapor. Single-phase dielectric coolants offer advantages such as chemical stability, non-conductivity, and ease of handling. However, challenges remain in optimizing the thermal transfer efficiency and coolant circulation within single-phase immersion systems.

In the example of FIG. 1, a line 132 represents the level of the dielectric coolant 131 in the immersion tank 130. Electronic modules 140 are submerged in the dielectric coolant 131, i.e., disposed below the line 132 in the immersion tank 130. In one embodiment, an electronic module 140 comprises a printed circuit board (PCB) that supports one or more processors 141 and other electronic components. A heatsink 142 or other surface for dissipating heat may be attached to a processor 141. A processor 141 may comprise a graphics processing unit (GPU), central processing unit (CPU), or other high heat-generating electronic component.

The immersion tank 130 includes an outlet 134 and an inlet 135. The dielectric coolant 131 comes into contact directly with the electronic components of electronic modules 140. Heat from the electronic components is transferred to the dielectric coolant 131, which flows out through the outlet 134 (see arrow 101). The CDU 150 cools the heated dielectric coolant 131 and pumps the cooled dielectric coolant 131 back to the immersion tank 130 through the inlet 135 (see arrow 104). The cooling loop between the CDU 150 and the immersion tank 130 is referred to as a secondary cooling loop 161. Generally, a cooling loop may comprise piping or other means for transporting the coolant.

In one embodiment, the CDU 150 includes a pump 151 for circulating the dielectric coolant 131 through the secondary cooling loop 161, and a heat exchanger 152 for cooling the dielectric coolant. In one embodiment, the heat exchanger 152 is a liquid-to-liquid heat exchanger, which receives the heated dielectric coolant 131 at a port 153 (see arrow 103), cools the dielectric coolant 131 using water that circulates through a primary cooling loop 162, and discharges the cooled dielectric coolant 131 at a port 154 (see arrow 104). The water in the primary cooling loop 162 may be supplied by a water tank 160.

In one embodiment, the fine bubble generator 120 is disposed in the secondary cooling loop 161, between the CDU 150 and the immersion tank 130. This advantageously allows the fine bubble generator 120 to be retrofitted into existing immersion cooling systems without necessarily having to access the CDU 150 or the immersion tank 130.

The fine bubble generator includes an intake port 121 for receiving the dielectric coolant 131 (see arrow 101), a discharge port 122 for discharging the dielectric coolant 131 and fine bubbles (see arrow 102), and a gas port 123 for receiving air from the immersion tank 130 (see arrow 105). In one embodiment, the pump 151 draws the dielectric coolant 131 from the immersion tank 130 into the fine bubble generator 120, thereby inducing negative pressure that draws air into the gas port 123. In one embodiment, air that is received at the gas port 123 of the fine bubble generator 120 is hot air that is immediately above the dielectric coolant 131 in the immersion tank 130 (see FIGS. 1, 133). The pump 151 circulates the fine bubbles and the dielectric coolant 131 in the secondary cooling loop 161 through the heat exchanger 152, the immersion tank 130, and the fine bubble generator 120.

Generally, bubbles are classified based on their size. Bubbles with a diameter of less than 100 micrometers are called “fine bubbles”. Among fine bubbles, those with a diameter between 1 and 100 micrometers are referred to as “microbubbles”, while those with a diameter less than 1 micrometer are called “ultrafine bubbles”.

The fine bubble generator 120 may be a commercially-available fine bubble generator. Experiments performed by the inventors indicate that existing fine bubble generators can generate bubbles ranging in size from 100 micrometers to 60 micrometers in dielectric coolant 131 comprising PAO4/PAO6 hydrocarbon oil. When a surfactant at 0.01 weight percent concentration is added to the PAO4/PAO6 hydrocarbon oil, the number of 100-micrometer bubbles generated increases by 20% to 25%, while the number of 60-micrometer bubbles generated increases by 40% to 45%. In one embodiment, the fine bubble generator 120 generates fine bubbles with a mean diameter between 1 μm to 100 μm, and bubble concentration between 9×10⁵ to 9×10⁶ particles/ml. As can be appreciated, the particulars of the fine bubble generator 120 and dielectric coolant 131 may be selected based on the requirements of a given immersion cooling application.

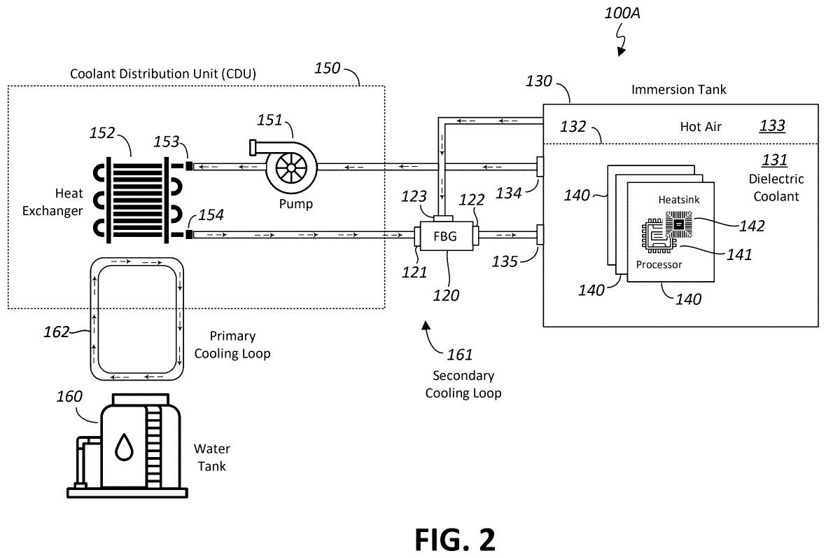

The fine bubble generator 120 may be disposed at other points in the secondary cooling loop 161. FIG. 2 shows an immersion cooling system 100A, in accordance with another embodiment of the present invention. The immersion cooling system 100A of FIG. 2 is an embodiment of the immersion cooling system 100 of FIG. 1 where the fine bubble generator 120 is disposed at the inlet 135 of the immersion tank 130. The immersion cooling system 100A is otherwise the same as the immersion cooling system 100.

More particularly, in the immersion cooling system 100A, the intake port 121 of the fine bubble generator 120 receives cooled dielectric coolant 131 from the port 154 of the heat exchanger 152, and the discharge port 122 of the fine bubble generator 120 discharges the cooled dielectric coolant 131 and generated fine bubbles to the inlet 135 of the immersion tank 130. Air from the immersion tank 130 is received at the gas port 123 of the fine bubble generator 120, and is dispersed to the dielectric coolant 131 in the fine bubble generator 120 to generate the fine bubbles. The heat exchanger 152, pump 151, water tank 160, and the immersion tank 130 are as described with reference to FIG. 1.

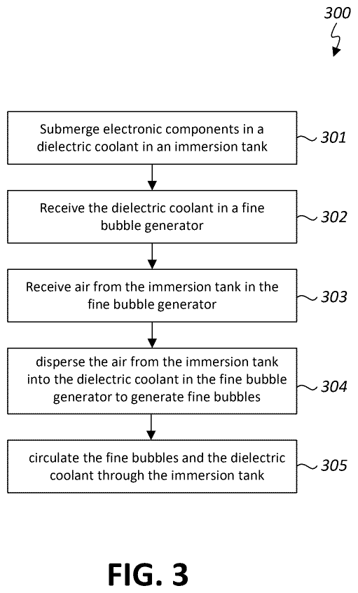

FIG. 3 shows a flow chart of a method 300 of immersion cooling electronic components, in accordance with an embodiment of the present invention.

In step 301, the method 300 includes submerging a plurality of electronic components in a dielectric coolant in an immersion tank. The electronic components may be mounted on corresponding electronic modules. The electronic components may be processors with attached heatsinks. In one embodiment, the dielectric coolant comprises a single-phase dielectric coolant, such as hydrocarbon oil. The dielectric coolant may include a surfactant to increase concentration of the bubbles.

In step 302, the method 300 includes receiving the dielectric coolant at an intake port of a fine bubble generator. The fine bubble generator may be disposed at various points in the cooling loop that includes a heat exchanger and the immersion tank.

In step 303, the method 300 includes receiving air from the immersion tank at a gas port of the fine bubble generator.

In step 304, the method 300 includes generating fine bubbles by dispersing the air from the immersion tank into the dielectric coolant in the fine bubble generator.

In step 305, the dielectric coolant and the fine bubbles are circulated through the immersion tank in the cooling loop.

The use of a fine bubble generator as disclosed herein provides many advantages, some of which are especially important in reducing coolant flow resistance.

First, the use of the fine bubble generator as disclosed herein has a lubricating effect. Micro-nano bubbles form a fine bubble layer within the dielectric coolant, which creates a lubricating film at solid interfaces, such as heatsinks, etc. This reduces friction between the dielectric coolant 131 and the boundary, thereby lowering viscosity.

Second, the use of the fine bubble generator as disclosed herein has a shear-thinning effect. The presence of fine bubbles can alter the shear rate distribution within the dielectric coolant. This localized flow variation can lead to a shear-thinning effect, reducing the overall viscosity of the dielectric coolant.

Third, the use of the fine bubble generator as disclosed herein promotes disturbance and turbulence. The movement of fine bubbles within the dielectric coolant 131 induces local disturbances and turbulence. These disturbances enhance internal mixing and momentum transfer, effectively decreasing the apparent viscosity of the dielectric coolant.

Fourth, the extremely small size of nanobubbles, combined with finely designed heatsink cooling fins (which increase surface area), can enhance heat dissipation efficiency.

Fifth, because the fine bubble generator as disclosed herein uses air from the immersion tank, the fine bubble generator does not need a power supply (i.e., electricity or battery supply). The fine bubble generator simply has to be designed with suitable porous structures that generate bubbles based on changes in flow rate and pressure within the piping of the secondary cooling loop.

Sixth, the fine bubble generator as disclosed herein does not need a dedicated gas tank that needs to be continually refilled.

Seventh, the fine bubble generator as disclosed herein enhances heat dissipation by drawing hot air from the immersion tank.

While specific embodiments of the present invention have been provided, it is to be understood that these embodiments are for illustration purposes and not limiting. Many additional embodiments will be apparent to persons of ordinary skill in the art reading this disclosure.

What is claimed is:

1. An immersion cooling system comprising:
an immersion tank that contains a single-phase dielectric coolant, wherein electronic modules are submerged in the single-phase dielectric coolant in the immersion tank;
a coolant distribution unit (CDU) comprising a pump and a heat exchanger, the CDU is coupled to draw the single-phase dielectric coolant from the immersion tank, cool the single-phase dielectric coolant, and discharge the single-phase dielectric coolant to the immersion tank in a first cooling loop; and
a fine bubble generator comprising an intake port, a discharge port, and a gas port, the fine bubble generator is disposed between the CDU and the immersion tank in the first cooling loop, the fine bubble generator is coupled to receive the single-phase dielectric coolant at the intake port, generate fine bubbles using air received at the gas port from the immersion tank, and discharge the single-phase dielectric coolant and the fine bubbles at the discharge port.

2. The immersion cooling system of claim 1, wherein the heat exchanger is a liquid-to-liquid heat exchanger that cools the single-phase dielectric coolant in the first cooling loop using water that is circulated in a second cooling loop.

3. The immersion cooling system of claim 2, wherein the water in the second cooling loop is supplied by a water tank.

4. The immersion cooling system of claim 1, wherein the fine bubble generator is disposed between an outlet of the immersion tank and a receiving port of the heat exchanger that receives the single-phase dielectric coolant, the intake port of the fine bubble generator is coupled to the outlet of the immersion tank and the discharge port of the fine bubble generator is coupled to the receiving port of the heat exchanger.

5. The immersion cooling system of claim 1, wherein the fine bubble generator is disposed between an inlet of the immersion tank and a discharging port of the heat exchanger that discharges the single-phase dielectric coolant, the discharge port of the fine bubble generator is coupled to the inlet of the immersion tank and the intake port of the fine bubble generator is coupled to the discharging port of the heat exchanger.

6. The immersion cooling system of claim 1, wherein the single-phase dielectric coolant comprises hydrocarbon oil.

7. The immersion cooling system of claim 6, wherein the single-phase dielectric coolant includes a surfactant.

8. A method of immersion cooling electronic components, the method comprising:
submerging a plurality of electronic components in a dielectric coolant in an immersion tank;
receiving the dielectric coolant in a fine bubble generator;
receiving air from the immersion tank in the fine bubble generator;
generating fine bubbles by dispersing the air received from the immersion tank into the dielectric coolant in the fine bubble generator; and
flowing the fine bubbles and the dielectric coolant into the immersion tank.

9. The method of claim 8, wherein the dielectric coolant is a single-phase dielectric coolant.

10. The method of claim 8, wherein the fine bubble generator is disposed between a coolant distribution unit (CDU) and the immersion tank.

11. The method of claim 8, wherein the fine bubble generator is disposed at an outlet of the immersion tank.

12. The method of claim 8, wherein the fine bubble generator is disposed at an inlet of the immersion tank.

13. The method of claim 8, wherein the dielectric coolant comprises hydrocarbon oil.

14. The method of claim 13, wherein the dielectric coolant includes a surfactant.

15. An immersion cooling system comprising:
an immersion tank that contains a dielectric coolant, wherein a plurality of electronic components is submerged in the dielectric coolant;
a heat exchanger comprising a first port that is coupled to an outlet of the immersion tank and a second port that is coupled to an inlet of the immersion tank; and
a fine bubble generator that is disposed between the immersion tank and the heat exchanger in a first cooling loop, the fine bubble generator comprising an intake port that receives the dielectric coolant, a gas port that receives air from the immersion tank for generating fine bubbles, and a discharge port that discharges the fine bubbles and the dielectric coolant.

16. The immersion cooling system of claim 15, further comprising a pump that circulates the dielectric coolant and the fine bubbles in the first cooling loop through the fine bubble generator, the heat exchanger, and the immersion tank.

17. The immersion cooling system of claim 15, wherein the dielectric coolant is a single-phase dielectric coolant.

18. The immersion cooling system of claim 15, wherein the fine bubble generator is disposed between the outlet of the immersion tank and the first port of the heat exchanger.

19. The immersion cooling system of claim 15, wherein the fine bubble generator is disposed between the inlet of the immersion tank and the second port of the heat exchanger.

20. The immersion cooling system of claim 15, wherein the dielectric coolant is circulated in the first cooling loop, and the heat exchanger cools the dielectric coolant using water that is circulated in a second cooling loop.
